(19) United States
(12) Patent Application Publication
(10) Pub. No.: US 2022/0185738 A1
(43) Pub. Date: Jun. 16, 2022

(54) CORROSION-RESISTANT CERAMIC

(71) Applicant: KYOCERA Corporation, Kyoto-shi, Kyoto (JP)

(72) Inventor: Manpei TANAKA, Higashiomi-shi, Shiga (JP)

(21) Appl. No.: 17/600,881

(22) PCT Filed: Apr. 1, 2020
(86) PCT No.: PCT/JP2020/015068

§ 371 Date: Oct. 1, 2021

(30) Foreign Application Priority Data
Apr. 2, 2019 (JP) 2019-070733

(51) Int. Cl. C04B 35/10; H01J 37/32; C04B 38/00

(52) U.S. Cl. CPC C04B 35/10; H01J 37/32495; H01J 37/3244; C04B 2235/9684; H01J 2237/334; C04B 2235/3222; C04B 2235/3279; C04B 38/0054

(57) ABSTRACT

A corrosion-resistant ceramic of the present disclosure contains aluminum oxide as a main component and a yttrium-aluminum composite oxide as a secondary component, and includes a plurality of open pores. When an average value of inter-centroid distances between adjacent open pores is denoted by L1, L1 is 50 μm or greater.

### TECHNICAL FIELD

The present disclosure relates to a corrosion-resistant ceramic, a plasma treatment device member, and a plasma treatment device.

### BACKGROUND ART

Plasma treatment devices are used to manufacture semiconductors and liquid crystal display devices. A plasma treatment device member used in such a plasma treatment device is exposed to plasma and therefore needs to have a high level of corrosion resistance.

Yttrium aluminum garnet sintered bodies are attracting attention as ceramics that satisfy such a requirement. However, while yttrium aluminum garnet sintered bodies have better corrosion resistance than aluminum oxide sintered bodies, mechanical characteristics such as fracture toughness are considerably inferior to those of aluminum oxide sintered bodies. Therefore, it is difficult to use a yttrium aluminum garnet sintered body as a plasma treatment device member, which requires such mechanical characteristics.

Based on these circumstances, Patent Document 1 proposes a corrosion-resistant member made from α-Al₂O₃ crystals and a sintered body including yttrium aluminum garnet (YAG) crystals, wherein the content of Al is from 70 mass % to 98 mass % in terms of Al₂O₃, the content of Y is from 2 mass % to 30 mass % in terms of Y₂O₃, the average crystal particle size of the α-Al₂O₃ crystals is from 1 μm to 10 μm, and the average crystal particle size of the YAG crystals is from 10% to 80% of the average crystal particle size of the α-Al₂O₃ crystals and also not less than 0.5 μm and not greater than 8 μm. Patent Document 1 also describes that it is preferable to have no more than two pores having a maximum diameter of greater than 10 μm at a grain boundary triple point (region at which three grain boundaries are joined) present in a 10 μm×10 μm region on the surface.

### CITATION LIST

### Patent Literature

Patent Document 1: JP 5159310 B

### SUMMARY

### Technical Problem

With the corrosion-resistant member described in Patent Document 1, when an open pore is included at each grain boundary triple point, the maximum value of the average crystal particle size of the α-Al₂O₃ crystals is 10 μm, and therefore the average value of the inter-centroid distances of the open pores, which is an indicator of the interval between the open pores, is 10 μm at the longest. When the interval between open pores is narrow in this way, it is difficult to obtain sufficient corrosion resistance, and therefore further improvement in corrosion resistance is required.

Thus, an object of the present disclosure is to provide a corrosion-resistant ceramic that exhibits a high level of corrosion resistance while maintaining mechanical characteristics, and also to provide a plasma treatment device member and a plasma treatment device.

### Solution to Problem

A corrosion-resistant ceramic of the present disclosure contains aluminum oxide as a main component and a yttrium-aluminum composite oxide as a secondary component, and includes a plurality of open pores. When an average value of inter-centroid distances between adjacent open pores is denoted by L1, L1 is 50 μm or greater.

The plasma treatment device member of the present disclosure contains the above-described corrosion-resistant ceramic. Furthermore, the plasma treatment device of the present disclosure is provided with the aforementioned plasma treatment device member and a plasma generating device.

### Advantageous Effects of Invention

According to the present disclosure, a corrosion-resistant ceramic that exhibits a high level of corrosion resistance while maintaining mechanical characteristics, and also a plasma treatment device member and a plasma treatment device can be provided.

### BRIEF DESCRIPTION OF DRAWINGS

FIG. 1 is a schematic view illustrating an overview of a plasma treatment device provided with a plasma treatment device member containing a corrosion-resistant ceramic of the present disclosure.

### DESCRIPTION OF EMBODIMENTS

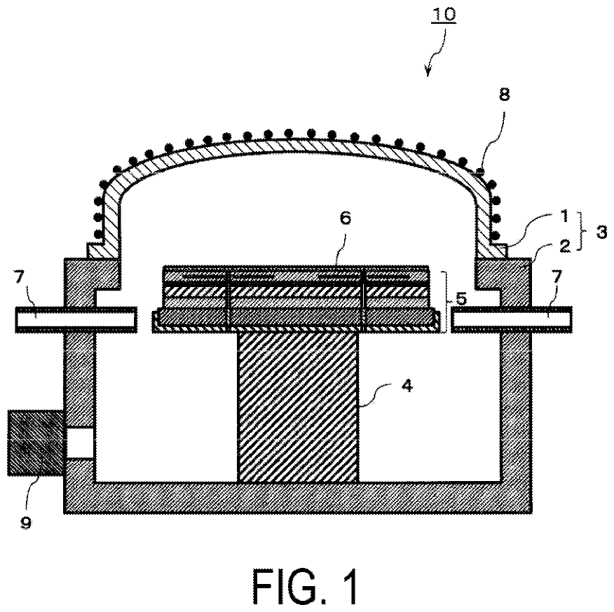

A corrosion-resistant ceramic, a plasma treatment device member, and a plasma treatment device according to the present disclosure will be described in detail below with reference to the drawings. FIG. 1 is a schematic view illustrating an overview of a plasma treatment device provided with a plasma treatment device member containing a corrosion-resistant ceramic of the present disclosure.

A plasma treatment device 10 illustrated in FIG. 1 is provided with a treatment chamber 3 including an upper container 1 having a dome shape, and a lower container 2 disposed below the upper container 1. A support table 4 is disposed inside the treatment chamber 3 at the lower container 2 side, and an electrostatic chuck 5, which is an example of an electrostatic attraction member, is provided on the support table 4. A DC power supply (not illustrated) is connected to an attraction electrode of the electrostatic chuck 5. A semiconductor substrate 6 is attracted to and supported on a placement surface of the electrostatic chuck 5 through the supply of electricity.

A vacuum pump 9 is connected to the lower container 2, and a vacuum state can be formed inside the treatment chamber 3. A gas nozzle 7 that supplies an etching gas is provided in a peripheral wall of the lower container 2. A peripheral wall of the upper container 1 is provided with an induction coil 8 that is electrically connected to an RF power supply.

When the semiconductor substrate 6 is to be etched using the plasma treatment device 10, first, the treatment chamber 3 is exhausted to a predetermined vacuum degree by the vacuum pump 9. Next, the semiconductor substrate 6 is attracted to the placement surface of the electrostatic chuck 5. Subsequently, electricity is supplied to the induction coil 8 from the RF power supply while an etching gas such as CF₄ gas is supplied through the gas nozzle 7. Through this supply of electricity, a plasma of the etching gas is formed in the internal space above the semiconductor substrate 6, and the semiconductor substrate 6 can be etched in a predetermined pattern.

Examples of the etching gas include halogen-based gases such as a fluorine-based gas that is a fluorine compound, such as CF₄, SF₆, CHF₃, ClF₃, NF₃, C₄F₈, or HF, a chlorine-based gas that is a chlorine compound, such as Cl₂, HCl, BCl₃, or CCl₄, or a bromine-based gas that is a bromine compound, such as Br₂, HBr, or BBr₃. These etching gases are highly corrosive.

The gas nozzle 7 described above is one embodiment of the plasma treatment device member of the present disclosure. The gas nozzle 7 contains a corrosion-resistant ceramic (hereinafter, the “corrosion-resistant ceramic” may be referred to as simply a “ceramic”) containing aluminum oxide as a main component and a yttrium-aluminum composite oxide as a secondary component, and including a plurality of open pores. In the ceramic, when the average value of the inter-centroid distances between adjacent open pores is denoted by L1, L1 is 50 μm or greater.

Aluminum oxide is a component for ensuring ceramic mechanical characteristics, and the yttrium-aluminum composite oxide is a component that exhibits high corrosion resistance against an etching gas G. Examples of the yttrium-aluminum composite oxide include YAG (3Y₂O₃.5Al₂O₃). YAM (2Y₂O₃.Al₂O₃), YAL (Y₂O₃.Al₂O₃), and YAP (YAlO₃).

When the interval L1 is within the abovementioned range, even if the etching gas comes into contact with the surface of the ceramic and particles are generated from the open pores, because the interval L1 is relatively large, the possibility of particles colliding with the contour (edge) of adjacent open pores is reduced, and new particles are less likely to be generated. In particular, the interval L1 is preferably 70 μm or greater.

In the present specification, a “main component of the ceramic” means a component that accounts for 70 mass % or more of the total of 100 mass % of the components constituting the ceramic. A secondary component is a component that is contained in the next largest amount after the main component, and the content thereof is from 2 mass % to 30 mass %. The content of the main component of the ceramic may be 75 mass % or greater. Each component constituting the ceramic can be identified by an X-ray diffractometer using CuKα radiation. The content of the main component can be determined by the Rietveld refinement technique.

In addition to the aluminum oxide and the yttrium-aluminum composite oxide, the corrosion-resistant ceramic may contain, for example, at least one element selected from silicon, iron, aluminum, calcium, and magnesium. The silicon content may be 300 ppm by mass or less in terms of SiO₂, the iron content may be 50 ppm by mass or less in terms of Fe₂O₃, the aluminum content may be 100 ppm by mass or less in terms of Al₂O₃, and the total content of calcium and magnesium may be 350 ppm by mass or less in terms of CaO and MgO, respectively. Furthermore, the content of carbon may be 100 ppm by mass or less.

The content of each component may be determined by using, for example, an inductively coupled plasma (ICP) emission spectrophotometer or a fluorescent X-ray analysis device. The carbon content may be determined using a carbon analyzer.

The corrosion-resistant ceramic may also contain, for example, nickel, and the nickel content is 4 ppm by mass or less in terms of NiO. When Ni oxidizes, variations in the color tone easily occur depending on the degree of oxidation, and such variations easily impair the product value. Therefore, the Ni content in terms of NiO preferably satisfies the aforementioned range, and in such a range, variations in color tone are suppressed and product value is improved. Here, the Ni content in terms of NiO may be determined by using a glow discharge mass spectrometer (GDMS).

When the inter-centroid distance of the open pores is to be determined, measurement is performed using an optical microscope with the magnification set to 200× and the measurement range of one location set to 7.1066×10⁵ μm². This measurement is performed at four locations whereby the inter-centroid distances of the open pores can be determined.

The inter-centroid distance between adjacent open pores can be determined by applying an inter-centroid distance measuring technique of the image analysis software “Azo-kun (Ver 2.52)” (trade name, available from Asahi Kasei Engineering Corporation) to this observation range as the measurement target. In the present disclosure, the inter-centroid distance of the open pores is the linear distance between centroids of the open pores.

As setting conditions for the method for measuring the inter-centroid distance, the measurement conditions are set as follows: the brightness of the particles is set to dark, the binarization method is set to manual, the threshold value is set from 190 to 220, and the small figure removal area is set to 1 μm², and a noise removal filter is used. When measurement as described above is performed, the threshold value is set from 190 to 220. However, the threshold value need only be adjusted according to the brightness of the image, which is within a range. Once the brightness of particles has been set to dark, the binarization method has been set to manual, the small figure removal area has been set to 1 μm², and a noise removal filter has been provided, the threshold value may be adjusted such that a marker appearing in the image matches the shape of an open pore.

When the number of open pores observed in each of the measurement ranges indicated above is one or less, the measurement range may be widened so that at least two or more open pores are present in the measurement range.

The kurtosis of the inter-centroid distances between open pores in the ceramic may be 0 or greater. When the kurtosis of the inter-centroid distances between open pores is within this range, the variation in the inter-centroid distances between the open pores becomes small. Furthermore, there is an increase in the number of open pores for which the inter-centroid distance between open pores is a value close to the average value. As a result, the expansion of micro-cracks in adjacent open pores is more likely to be suppressed, and reliability is improved. In particular, the kurtosis of the inter-centroid distances between open pores is preferably 0.05 or greater.

Here, a kurtosis Ku is an index (statistical amount) indicating to what extent the peak and tails of a distribution differ from those of normal distribution. If the kurtosis Ku is greater than 0, a distribution with a sharp peak is obtained. If the kurtosis Ku is equal to 0, the distribution becomes a normal distribution. If the kurtosis Ku is less than 0, the distribution becomes a distribution with a rounded peak.

The average value of the diameters of the open pores in the ceramic may be 2.5 μm or less. If the average value of the diameters of the open pores is 2.5 μm or less, there is a reduction in particles entering the open pores. Further, when the amount of particles entering the open pores is small, damage to the wall surfaces of the open pores and the generation of new particles are less likely to occur. In particular, the average value of the diameters of the open pores in the ceramic is preferably 0.2 μm or less.

The kurtosis of the diameters of the open pores in the ceramic may be 0 or greater. When the kurtosis of the diameters of the open pores is within this range, the variation in the diameters of the open pores is small, and there is an increase in the number of open pores for which the diameter of the open pore is a value close to the average value. As a result, the number of open pores with an unusually large diameter decreases, and impurities originating from the inside of the open pores can be reduced. In particular, the kurtosis of the inter-centroid distances between open pores is preferably 0.5 or greater.

The coefficient of variation of the diameters of the open pores in the ceramic may be 0.7 or less. When the coefficient of variation of the diameters of the open pores is 0.7 or less, the number of open pores having an abnormally large diameter is reduced. As a result, impurities originating from the inside of the open pores can be further reduced.

The surface area ratio of the open pores in the ceramic may be 0.1% or less. As the number of open pores decreases, corrosion resistance increases. In particular, the surface area ratio of the open pores is preferably 0.05% or less.

In addition to the inter-centroid distances, the average value of the diameters of the open pores, the coefficient of variation of the diameters of the open pores, and the surface area ratio of the open pores can be determined by using the image analysis software “Win ROOF (Ver. 6.1.3)” (available from Mitani Corporation). Specifically, these values are measured with the magnification set to 200×, the measurement range of one location set to 7.1066×10⁵ μm², and the threshold value of an equivalent circle diameter corresponding to the diameter set to 0.21 μm. This measurement is performed at four locations, whereby the average value of the diameters of the open pores, the coefficient of variation of the diameters of the open pores, and the surface area ratio of the open pores can be determined. The kurtosis Ku of the diameters of the open pores and the kurtosis Ku of the inter-centroid distances of the open pores may be determined using the function KURT available in Excel (trade name, available from Microsoft Corporation).

With the ceramic having a shape that is a cylindrical body, in a cross-section including an inner circumferential surface of the cylindrical body, the concentration of silicon on the inner circumferential surface may be higher than the concentration of silicon on a virtual circumferential surface parallel to the inner circumferential surface, where the virtual circumferential surface is positioned between the inner circumferential surface and an outer circumferential surface. The contact angle of silicon with respect to pure water is small. Therefore, when the concentration of silicon on the inner circumferential surface is higher than the concentration of silicon on the virtual circumferential surface, for a case in which the ceramic is washed using a water-soluble detergent, the removal efficiency of contamination from the inner circumferential surface, where the contamination is easily generated by the supply of etching gas, can be increased.

On the other hand, when the concentration of silicon on the virtual circumferential surface is lower than the concentration of silicon on the inner circumferential surface, the generation of mullite having a coefficient of linear expansion that differs from that of aluminum oxide and yttrium-aluminum composite oxide is suppressed internally. As a result, strain generated between the interior and a surface layer section including the inner circumferential surface can be reduced.

Next, an embodiment of a method for manufacturing a ceramic and a plasma treatment device member according to the present disclosure will be described. First, a powder containing aluminum oxide as a main component, a powder containing yttrium oxide as a main component (hereinafter, the powder containing aluminum oxide as a main component and the powder containing yttrium oxide as a main component may be collectively referred to as a “ceramic powder”), a wax, a dispersing agent, and a plasticizer are prepared.

With respect to a total of 100 parts by mass of the ceramic powder, for example, the wax is used at a proportion of from 10 parts by mass to 16 parts by mass, the dispersing agent is used at a proportion of from 0.1 parts by mass to 0.6 parts by mass, and the plasticizer is used at a proportion of from 1.0 part by mass to 1.8 parts by mass. Here, in 100 mass % of the ceramic powder, the powder containing aluminum oxide as a main component is contained at a proportion of from 70 mass % to 98 mass %, and the powder containing yttrium oxide as a main component is contained at a proportion of from 2 mass % to 30 mass %.

For example, the ceramic powder, the wax, the dispersing agent, and the plasticizer may all be heated at a temperature from 70° C. to 130° C., and stored in a resin container. At this time, the wax, the dispersing agent, and the plasticizer are normally liquids. Storing these materials in a container at such a temperature makes it easier to obtain a ceramic having a kurtosis of the inter-centroid distances between open pores of 0 or greater. Further, by heating at a temperature from 90° C. to 130° C., a ceramic having a kurtosis of the inter-centroid distances between open pores of 0 or greater is more easily obtained.

Next, the container is placed in a stirrer, and the ceramic powder, wax, dispersing agent, and plasticizer are stirred by rotating the container for one minute or longer (a rotary kneading process) to yield a slurry. The yielded slurry is filled into a syringe and subjected to defoaming while the syringe is rotated for one minute or longer by using a defoaming jig. In order to obtain a ceramic in which the kurtosis of the diameters of the open pores is 0 or greater, the slurry need only be pre-heated at a temperature of from 100° C. to 190° C. before being subjected to the defoaming treatment.

Next, the syringe filled with the defoamed slurry is mounted to an injection molding machine, the defoamed slurry is molded while the temperature of the slurry is maintained at 70° C. or higher, and a cylindrical molded article is obtained. A channel through which the slurry passes in the injection molding machine is also preferably maintained at 70° C. or higher. The temperature of the slurry may be maintained at 90° C. or higher, and the channel through which the slurry passes may also be maintained at 90° C. or higher.

The obtained molded article is sequentially degreased and fired to yield a sintered body. This sintered body corresponds to the ceramic of the present disclosure. Here, for example, the firing atmosphere is preferably an air atmosphere, the temperature elevation rate is preferably from 10° C./hr to 50° C./hr, the firing temperature is preferably from 1500° C. to 1700° C., the retention time is preferably from 1.5 hours to 5 hours, and the temperature decrease rate from the firing temperature to 1000° C. is preferably 100° C./hr.

To obtain a ceramic in which the average diameter of the open pores is 2.5 μm or less, the firing atmosphere is preferably an air atmosphere, the firing temperature is preferably from 1550° C. to 1700° C., and the retention time is preferably from 1.5 hours to 5 hours.

To obtain a ceramic in which the coefficient of variation of the diameters of the open pores is 0.7 or less, the firing atmosphere is preferably an air atmosphere, the firing temperature is preferably from 1550° C. to 1700° C., and the retention time is preferably from 2 hours to 5 hours.

To obtain a ceramic in which the surface area ratio of open pores is 0.1% or less, the firing atmosphere is preferably an air atmosphere, the firing temperature is preferably from 1600° C. to 1700° C., and the retention time is preferably from 1.5 to 5 hours.

Next, the surface of the sintered body can be mechanically machined to obtain a gas nozzle, which is one embodiment of a plasma treatment device member.

As described above, in the present disclosure, a plasma treatment device member is produced by molding using an injection molding machine.

Therefore, unlike a case of using an extrusion molding method or a machining method in which through holes are mechanically formed using a tool such as a drill after dry pressure molding, the interval between open pores is widened. As a result, a plasma treatment device member having excellent corrosion resistance can be formed.

The present disclosure is not limited to the above-described embodiment, and various modifications, improvements, combinations, and the like may be made within a range that does not depart from the gist of the present disclosure.

### REFERENCE SIGNS LIST

1 Upper container
2 Lower container
3 Treatment chamber
4 Support table
5 Electrostatic chuck
6 Semiconductor substrate
7 Gas nozzle
8 Induction coil
9 Vacuum pump
10 Plasma treatment device

1. A corrosion-resistant ceramic comprising aluminum oxide as a main component and a yttrium-aluminum composite oxide as a secondary component and further comprising a plurality of open pores, wherein, when an average value of inter-centroid distances between adjacent open pores is denoted by L1, L1 is 50 μm or greater.

2. The corrosion-resistant ceramic according to claim 1, wherein a kurtosis of the inter-centroid distances of the open pores is 0 or greater.

3. The corrosion-resistant ceramic according to claim 1, wherein the average value of the diameters of the open pores is 2.5 μm or less.

4. The corrosion-resistant ceramic according to claim 3, wherein a kurtosis of the diameters of the open pores is 0 or greater.

5. The corrosion-resistant ceramic according to claim 3, wherein a coefficient of variation of the diameters of the open pores is 0.7 or less.

6. The corrosion-resistant ceramic according to claim 1, wherein a surface area ratio of the open pores is 0.1% or less.

7. The corrosion-resistant ceramic according to claim 1,
wherein the corrosion-resistant ceramic has a shape of a cylindrical body, and
in a cross section comprising an inner circumferential surface of the cylindrical body, a concentration of silicon on the inner circumferential surface is higher than a concentration of silicon on a virtual circumferential surface parallel to the inner circumferential surface, the virtual circumferential surface being located between the inner circumferential surface and an outer circumferential surface.

8. The corrosion-resistant ceramic according to claim 1, further comprising nickel,
wherein a content of the nickel is 4 ppm by mass or less in terms of NiO.

9. A plasma treatment device member comprising the corrosion-resistant ceramic described in claim 1.

10. A plasma treatment device comprising the plasma treatment device member described in claim 9 and a plasma generating device.
